(19) United States
(12) Patent Application Publication
(10) Pub. No.: US 2026/0113033 A1
(43) Pub. Date: Apr. 23, 2026

(54) ISOLATION SWITCH

(71) Applicant: ROHM CO., LTD., Kyoto-shi (JP)

(72) Inventor: Koji SAITO, Kyoto (JP)

(21) Appl. No.: 19/357,535

(22) Filed: Oct. 14, 2025

(30) Foreign Application Priority Data
Oct. 21, 2024 (JP) 2024-184840

(51) Int. Cl. H03K 17/691; H02M 1/08; H03K 17/74

(52) U.S. Cl. CPC H03K 17/691; H02M 1/08; H03K 17/74; H03K 2217/0081

(57) ABSTRACT

An isolation switch includes a switch circuit connected between a first node and a second node so as to be turned on and off by a switch drive signal; a first transformer and a second transformer having a first primary side coil and a second primary side coil connected in parallel between a power supply terminal and a ground terminal, and a first secondary side coil and a second secondary side coil connected in series; a first pulse generation circuit and a second pulse generation circuit configured to pulse-drive the first primary side coil and the second primary side coil, respectively, in accordance with an input pulse; and a switch driving circuit configured to receive induction voltages generated in the first secondary side coil and the second secondary side coil, respectively, so as to generate the switch drive signal.

### CROSS REFERENCE TO RELATED APPLICATIONS

The present invention claims priority under 35 U.S.C. § 119 to Japanese Application No. 2024-184840 filed on Oct. 21, 2024, the entire contents of which are hereby incorporated by reference.

### BACKGROUND OF THE INVENTION

### Field of the Invention

The present disclosure relates to an isolation switch.

### Description of Related Art

Conventionally, an isolation switch, which is configured to electrically isolate between a primary circuit system and a secondary circuit system, and to drive a switch element in the secondary circuit system in accordance with a control signal of a primary circuit system, is used in various applications (such as a power supply device or a motor driving device).

Note that, as an example of a conventional technique related to the above description, there is WO2022/070944 applied by the present applicant.

### BRIEF DESCRIPTION OF THE DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram illustrating a comparative example of an isolation switch.

FIG. 11 is a diagram illustrating a first embodiment of the isolation switch.

FIG. 12 is a diagram illustrating a second embodiment of the isolation switch.

FIG. 13 is a diagram illustrating a third embodiment of the isolation switch.

FIG. 14 is a diagram illustrating a fourth embodiment of the isolation switch.

FIG. 15 is a diagram illustrating one configuration example of a controller.

FIG. 16 is a diagram illustrating one variation of the controller.

FIG. 17 is a diagram illustrating a fifth embodiment of the isolation switch.

FIG. 18 is a diagram illustrating a sixth embodiment of the isolation switch.

FIG. 19 is a diagram illustrating a seventh embodiment of the isolation switch.

FIG. 20 is a diagram illustrating an eighth embodiment of the isolation switch.

FIG. 21 is a diagram illustrating a ninth embodiment of the isolation switch.

FIG. 22 is a diagram illustrating a tenth embodiment of the isolation switch.

FIG. 23 is a diagram illustrating one configuration example of a voltage control circuit.

### DETAILED DESCRIPTION OF THE PREFERRED EMBODIMENTS

### Signal Transmission Device (Basic Configuration)

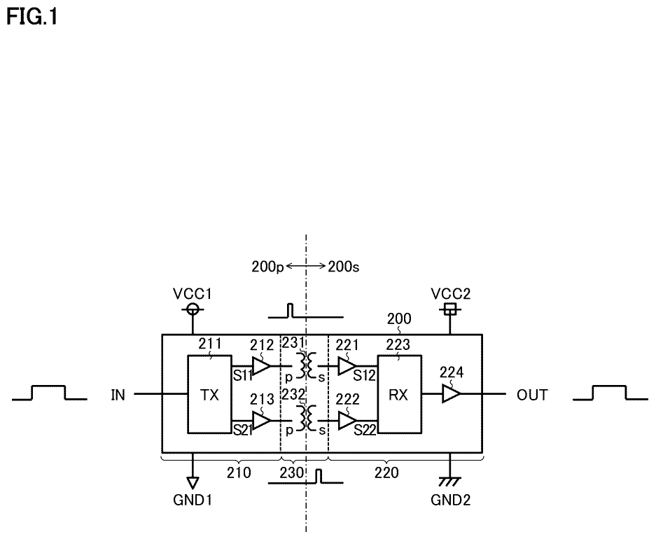

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

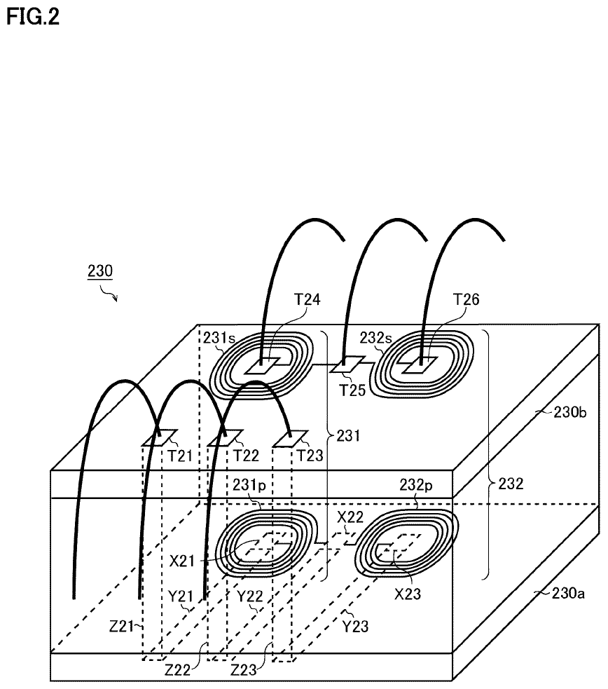

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (Two-Channel Type)

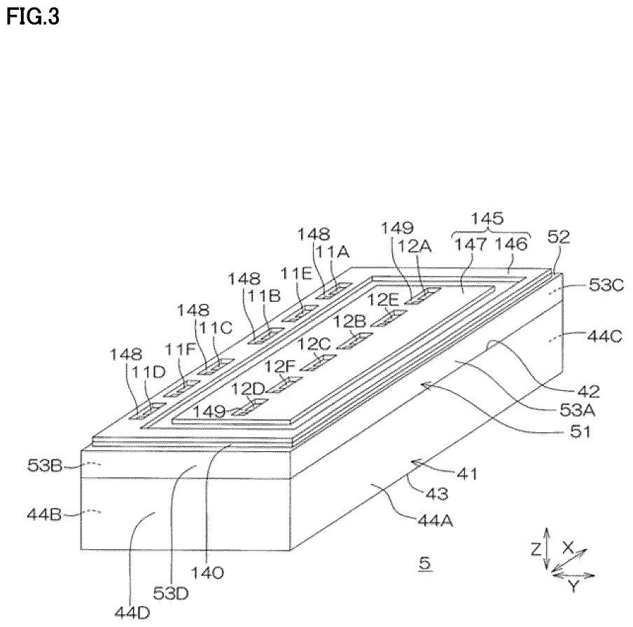

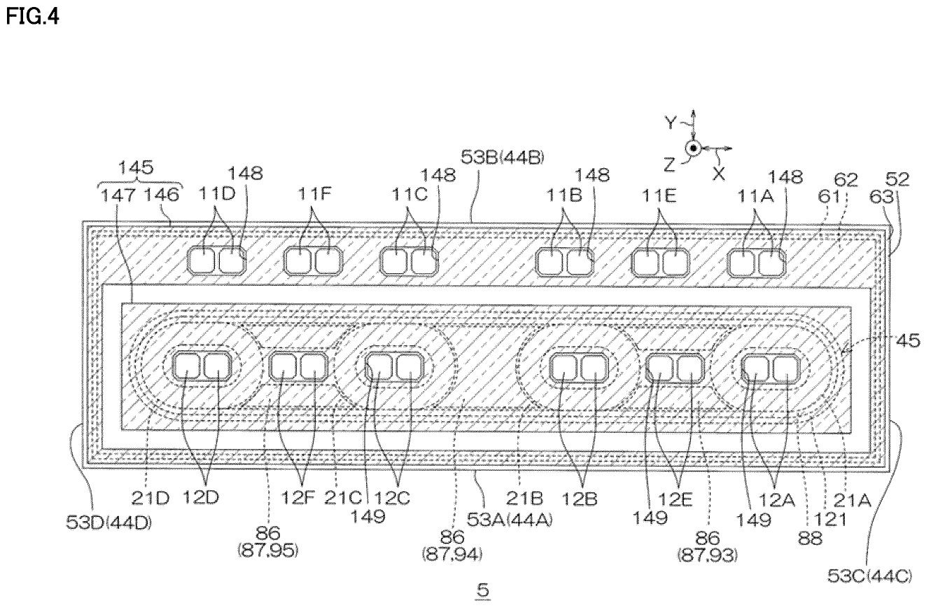

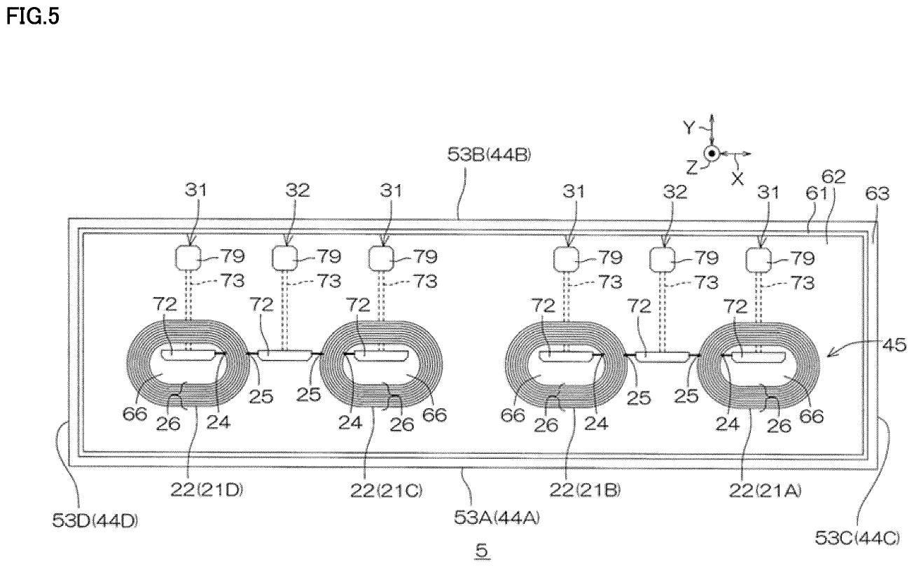

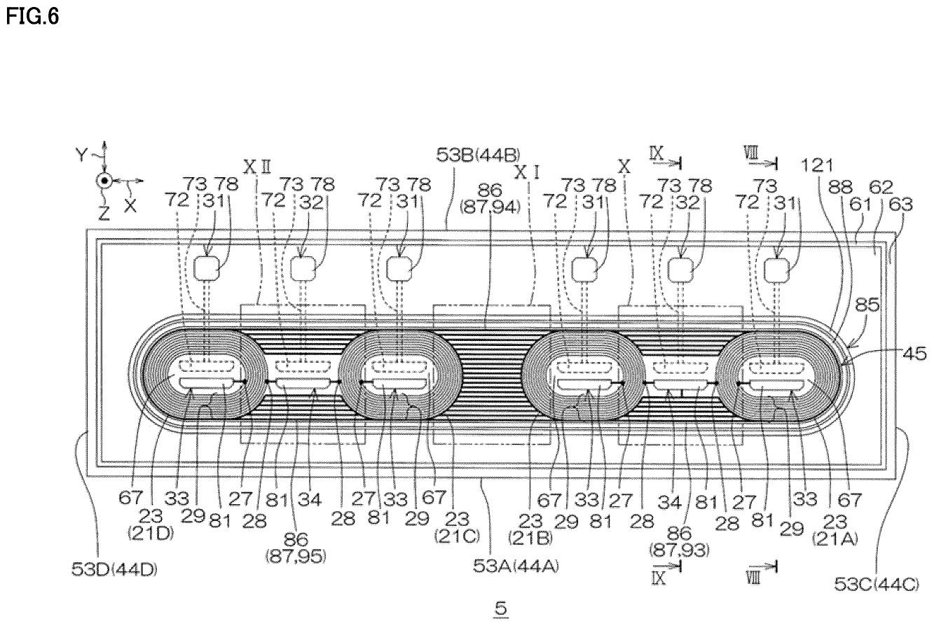

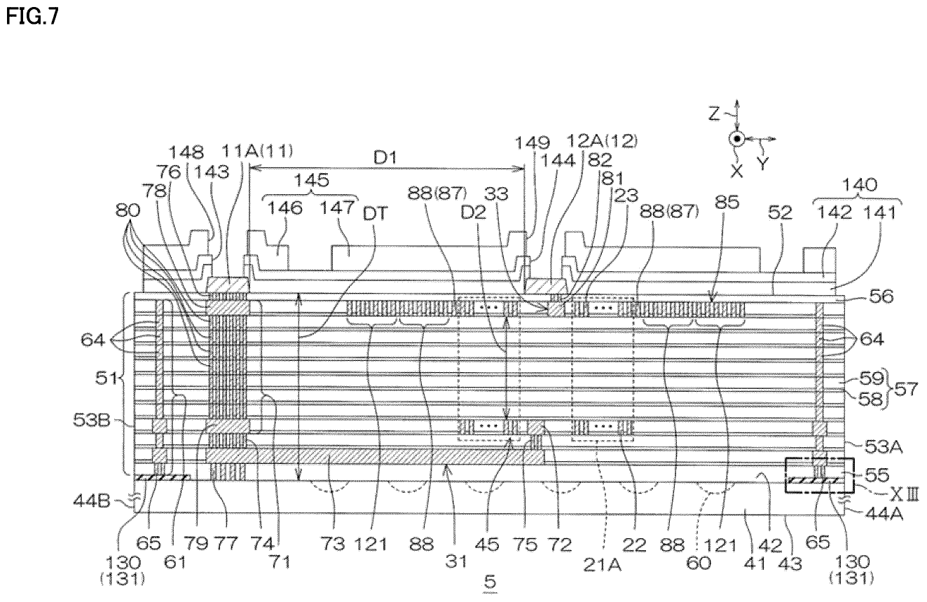

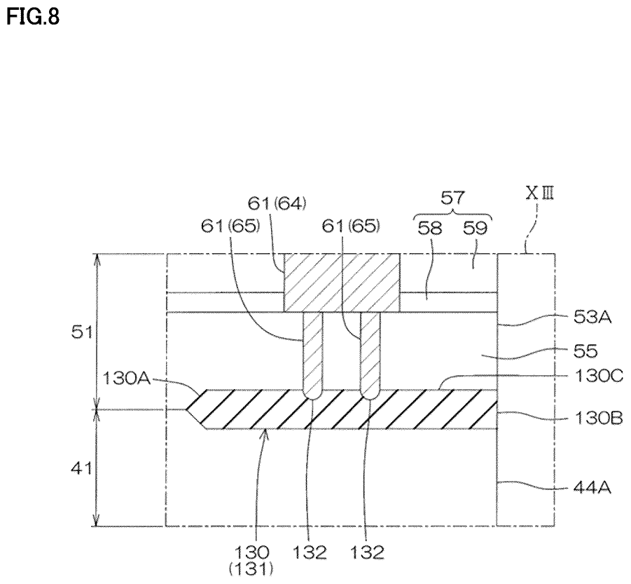

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any value, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential, and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

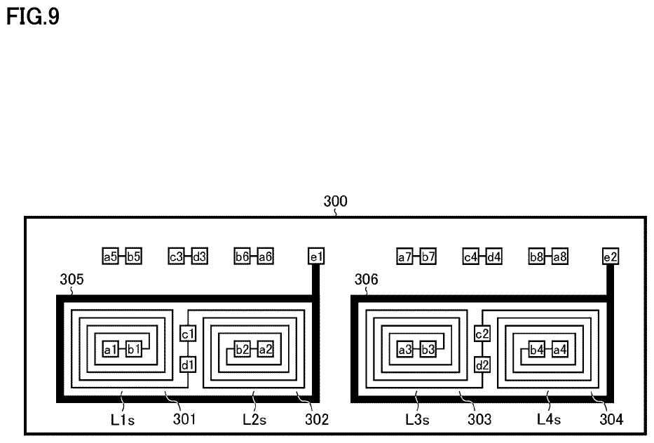

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300.

This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Isolation Switch (Comparative Example)

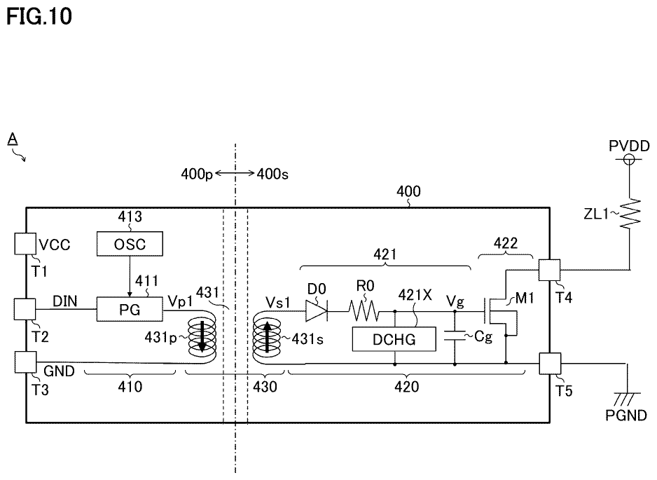

FIG. 10 is a diagram illustrating a comparative example of an isolation switch 400 (i.e., an example of a circuit configuration to be compared with an embodiment described later). The isolation switch 400 of this comparative example insulates between a primary circuit system 400p (VCC-GND system) and a secondary circuit system 400s (PVDD-PGND system) and transmits a pulse signal from the primary circuit system 400p to the secondary circuit system 400s.

Note that the isolation switch 400 can be mounted in an electronic device A together with a load ZL1. The electronic device A may be, for example, an industrial machine or an in-vehicle device. Note that the isolation switch 400 may be provided in a market, as a semiconductor integrated circuit device (so-called isolation switch IC) in which the isolation switch 400 is integrated.

The isolation switch 400 has external terminals T1 to T5 as means for establishing electrical connection with the outside of the device. The external terminal T1 is connected to an application terminal of a power supply voltage VCC. The external terminal T2 is connected to an application terminal of an input pulse signal DIN. The external terminal T3 is connected to an application terminal of a ground voltage GND. The external terminal T4 is connected to a first terminal of the load ZL1. A second terminal of the load ZL1 is connected to an application terminal of a power supply voltage PVDD. The external terminal T5 is connected to an application terminal of a ground voltage PGND.

In addition, the isolation switch 400 includes a primary side circuit 410, a secondary side circuit 420, and an insulation circuit 430.

The primary side circuit 410 is disposed in the primary circuit system 400p. With reference to this diagram, the primary side circuit 410 includes a pulse generation circuit 411 and an oscillation circuit 413.

The pulse generation circuit 411 generates a transmission pulse signal Vp1 in accordance with a logic level of the input pulse signal DIN. For instance, the pulse generation circuit 411 generates the transmission pulse signal Vp1 when the input pulse signal DIN is at high level. On the other hand, the pulse generation circuit 411 stops generation of the transmission pulse signal Vp1 when the input pulse signal DIN is at low level. The transmission pulse signal Vp1 may be pulse-driven between the power supply voltage VCC and the ground voltage GND, for example.

The oscillation circuit 413 supplies a clock signal to the pulse generation circuit 411. The transmission pulse signal Vp1 is pulse-driven in synchronization with a clock signal output from the oscillation circuit 413.

The secondary side circuit 420 is disposed in the secondary circuit system 400s. With reference to this diagram, the secondary side circuit 420 includes a switch driving circuit 421 and a switch circuit 422.

The switch driving circuit 421 generates a switch drive signal Vg in accordance with an induction voltage Vs1, for example. With reference to this diagram, the switch driving circuit 421 includes a diode D0, a resistor R0, a capacitor Cg, and a discharge circuit 421X.

The anode of the diode D0 is connected to an application terminal of the induction voltage Vs1. The cathode of the diode D0 is connected to a first terminal of the resistor R0. A second terminal of the resistor R0 and first terminals of the capacitor Cg and the discharge circuit 421X are each connected to an application terminal of the switch drive signal Vg. Second terminals of the capacitor Cg and the discharge circuit 421X are each connected to the external terminal T5. The capacitor Cg may be a parasitic capacitor that accompanies between the gate and the source of a transistor M1 described later. Note that the diode D0, the resistor R0, and the capacitor Cg rectify and smooth the induction voltage Vs1, so as to generate the switch drive signal Vg.

The switch circuit 422 is connected between the external terminal T4 and the external terminal T5 and is turned on and off by the switch drive signal Vg. The external terminal T4 corresponds to a first node. The external terminal T5 corresponds to a second node.

For instance, the switch circuit 422 includes the transistor M1 that conducts or cuts off between the external terminal T4 and the external terminal T5, in accordance with the switch drive signal Vg. The transistor M1 may be an N-channel type MOS [metal oxide semiconductor] field-effect transistor, for example. The drain of the transistor M1 is connected to the external terminal T4. The source and the backgate of the transistor M1 are connected to the external terminal T5. The gate of the transistor M1 is connected to the application terminal of the switch drive signal Vg. The transistor M1 can be understood as an output transistor having the gate connected to the application terminal of the switch drive signal Vg.

The insulation circuit 430 insulates between the pulse generation circuit 411 and the switch driving circuit 421 in a DC manner and transmits the transmission pulse signal Vp1 of the primary circuit system 400p as the induction voltage Vs1 of the secondary circuit system 400s. With reference to this diagram, the insulation circuit 430 includes a transformer 431. The transformer 431 includes a primary side coil 431p and a secondary side coil 431s.

A first terminal of the primary side coil 431p is connected to an application terminal of the transmission pulse signal Vp1. A second terminal of the primary side coil 431p is connected to the external terminal T3. A first terminal of the secondary side coil 431s is connected to the application terminal of the induction voltage Vs1. The induction voltage Vs1 corresponds to a received pulse signal generated on the secondary side coil 431s. A second terminal of the secondary side coil 431s is connected to the external terminal T5. The secondary side coil 431s is electromagnetically coupled to the primary side coil 431p. A turns ratio between the primary side coil 431p and the secondary side coil 431s can be adjusted so that the switch drive signal Vg should exceed the ON threshold value voltage Vth(M1) of the transistor M1, when the transmission pulse signal Vp1 is pulse-driven.

Next, a basic operation of the isolation switch 400 is described below. During a high level period of the input pulse signal DIN, the transmission pulse signal Vp1 applied to the primary side coil 431p is pulse-driven. In this case, the secondary side coil 431s generates the induction voltage Vs1. The induction voltage Vs1 is rectified and smoothed, and hence the switch drive signal Vg is raised to a signal level higher than the ON threshold value voltage Vth(M1) of the transistor M1. As a result, the transistor M1 becomes ON state, and hence the load ZL1 can be supplied with a drive current.

On the other hand, during a low level period of the input pulse signal DIN, the pulse drive of the transmission pulse signal Vp1 is stopped. Therefore, the induction voltage Vs1 is not generated as well. In this case, the switch drive signal Vg is decreased to a signal level lower than the ON threshold value voltage Vth(M1) of the transistor M1, by the action of the discharge circuit 421X. As a result, the transistor M1 becomes OFF state, and hence the load ZL1 is not supplied with the drive current.

In this way, by magnetic coupling using the transformer 431, the isolation switch 400 of this comparative example insulates between the primary circuit system 400p and the secondary circuit system 400s, and transmits a pulse signal from the primary circuit system 400p to the secondary circuit system 400s.

### Consideration about Switch Drive Signal Vg

Conventionally, as the transistor M1, a DMOS [double-diffused MOS] device or a CMOS [complementary MOS] device is widely and generally used. If the power supply voltage PVDD of the secondary circuit system 400s is approximately 10 to 40 V, the device selection described above does not cause any trouble.

However, in recent years, there is a demand or use for applying a high voltage up to 600 V as the power supply voltage PVDD. The DMOS device or the CMOS device described above may not be able to withstand application of such high voltage. For this reason, in order to support the above demand, as the transistor M1, it is necessary to use a device having a higher withstand voltage than the DMOS device or the CMOS device, e.g., to use a GaN device such as a GaN-HEMT [high electron mobility transistor], or an SiC device such as a SiC-MOSFET.

However, the ON threshold value voltage of a GaN device or an SiC device is higher than that of the DMOS device or the CMOS device. For this reason, a mechanism for increasing high level of the switch drive signal Vg is necessary.

In consideration of the above, the following description proposes a new embodiment that can increase high level of the switch drive signal Vg.

### Isolation Switch (First Embodiment)

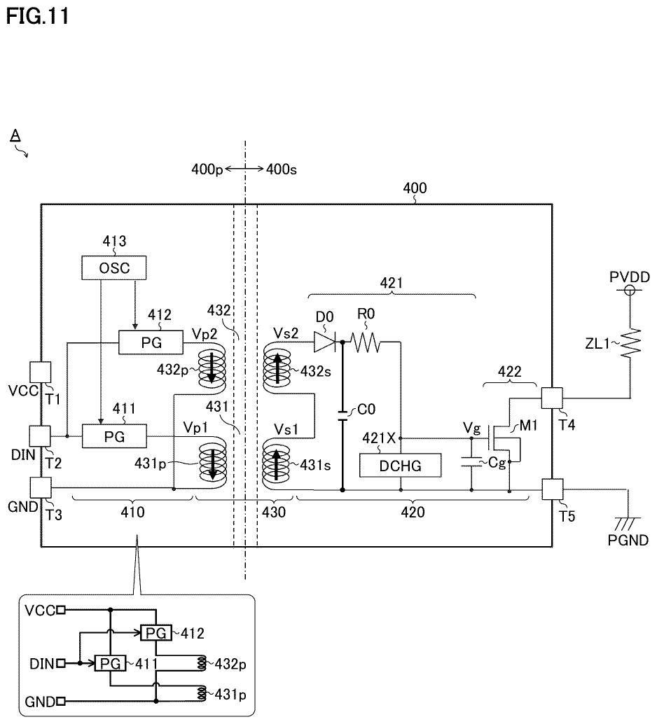

FIG. 11 is a diagram illustrating a first embodiment of the isolation switch 400. The isolation switch 400 of this embodiment uses the above comparative example (FIG. 10) as a base, and further includes a pulse generation circuit 412 and a transformer 432. Note that the transistor M1 may be a GaN device or an SiC device.

As described above, the pulse generation circuit 411 generates the transmission pulse signal Vp1 in accordance with a logic level of the input pulse signal DIN. For instance, the pulse generation circuit 411 generates the transmission pulse signal Vp1 when the input pulse signal DIN is at high level. On the other hand, the pulse generation circuit 411 stops generation of the transmission pulse signal Vp1 when the input pulse signal DIN is at low level. The transmission pulse signal Vp1 may be pulse-driven between the power supply voltage VCC and the ground voltage GND, for example.

The pulse generation circuit 412 generates a transmission pulse signal Vp2 in accordance with a logic level of the input pulse signal DIN. For instance, the pulse generation circuit 412 generates the transmission pulse signal Vp2 when the input pulse signal DIN is at high level. On the other hand, the pulse generation circuit 412 stops generation of the transmission pulse signal Vp2 when the input pulse signal DIN is at low level. The transmission pulse signal Vp2 may be pulse-driven between the power supply voltage VCC and the ground voltage GND, for example.

In other words, the pulse generation circuits 411 and 412 perform pulse drives of the primary side coils 431p and 432p, respectively, when the input pulse signal DIN is at high level. On the other hand, the pulse generation circuits 411 and 412 stop the pulse drives of the primary side coils 431p and 432p, respectively, when the input pulse signal DIN is at low level.

The oscillation circuit 413 supplies the same clock signal to the pulse generation circuits 411 and 412. The transmission pulse signals Vp1 and Vp2 are pulse-driven in synchronization with the clock signal output from the oscillation circuit 413.

As described above, the transformer 431 includes the primary side coil 431p and the secondary side coil 431s. In addition, the transformer 432 includes a primary side coil 432p and a secondary side coil 432s.

The first terminal of the primary side coil 431p is connected to the application terminal of the transmission pulse signal Vp1. A first terminal of the primary side coil 432p is connected to an application terminal of the transmission pulse signal Vp2. Second terminals of the primary side coils 431p and 432p are connected to the external terminal T3. In other words, the primary side coils 431p and 432p are connected in parallel between an application terminal of the power supply voltage VCC and an application terminal of the ground voltage GND, as illustrated in the balloon frame. Further, in accordance with the input pulse signal DIN, conduction/non-conduction of each of the primary side coils 431p and 432p is switched.

The first terminal of the secondary side coil 431s is connected to a first terminal of the secondary side coil 432s. The second terminal of the secondary side coil 431s is connected to the external terminal T5. A second terminal of the secondary side coil 432s is connected to the anode of the diode D0. In other words, the secondary side coils 431s and 432s are connected in series.

Note that the secondary side coil 431s is electromagnetically coupled to the primary side coil 431p. The secondary side coil 432s is electromagnetically coupled to the primary side coil 432p. The turns ratio between the primary side coil 431p and the secondary side coil 431s, as well as the turns ratio between the primary side coil 432p and the secondary side coil 432s, can be adjusted so that the switch drive signal Vg should exceed the ON threshold value voltage Vth(M1) of the transistor M1 when the transmission pulse signals Vp1 and Vp2 are pulse-driven.

The switch driving circuit 421 receives the induction voltages Vs1 and Vs2 generated in the secondary side coils 431s and 432s, respectively, and generates the switch drive signal Vg. For instance, the switch driving circuit 421 rectifies the sum voltage of the induction voltage Vs1 generated in the secondary side coil 431s and the induction voltage Vs2 generated in the secondary side coil 432s (i.e., Vs1+Vs2), so as to generate the switch drive signal Vg. The switch driving circuit 421 includes a capacitor C0 in addition to the component elements of the comparative example (FIG. 10). The capacitor C0 is connected between the cathode of the diode D0 and the external terminal T5.

Compared with the comparative example described above (FIG. 10), the isolation switch 400 of this embodiment can increase high level of the switch drive signal Vg. Therefore, the transistor M1 can turn on and off the GaN device or the SiC device without a trouble. As a result, high voltage drive of the load ZL1 can be performed.

### Isolation Switch (Second Embodiment)

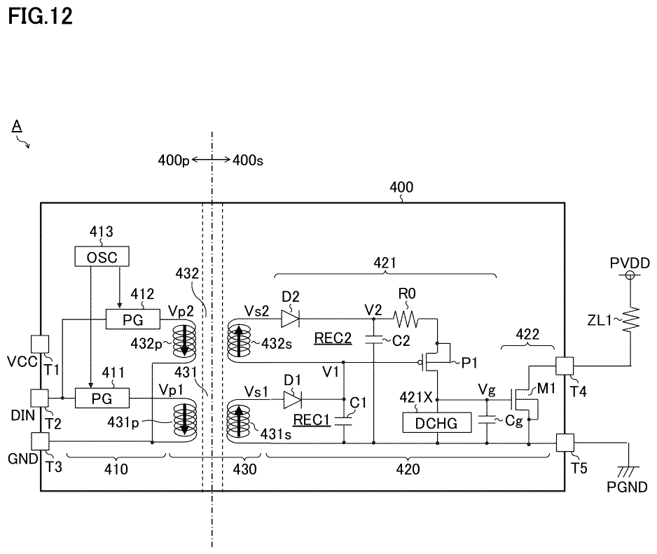

FIG. 12 is a diagram illustrating a second embodiment of the isolation switch 400. The isolation switch 400 of this embodiment uses the first embodiment described above (FIG. 11) as a base, and the configuration of the switch driving circuit 421 is modified.

With reference to this diagram, the switch driving circuit 421 includes capacitors C1 and C2, diodes D1 and D2, a transistor P1, and a resistor R2, instead of the diode D0 and the resistor R0 described above. The transistor P1 may be a P-channel type, for example.

The first terminal of the secondary side coil 431s and the anode of the diode D1 are connected to the application terminal of the induction voltage Vs1. The cathode of the diode D1 and a first terminal of the capacitor C1 are connected to an application terminal of a rectified voltage V1. The second terminal of the secondary side coil 431s and a second terminal of the capacitor C1 are connected to the external terminal T5. The diode D1 and the capacitor C1 can be understood as a rectifying circuit REC1, which rectifies and smooths the induction voltage Vs1 generated in the secondary side coil 431s so as to generate the rectified voltage V1. The capacitor C1 may have a capacitance of 10 pF, for example.

The first terminal of the secondary side coil 432s and the anode of the diode D2 is connected to an application terminal of the induction voltage Vs2. The cathode of the diode D2 and first terminals of the resistor R0 and the capacitor C2 are connected to an application terminal of a rectified voltage V2. The second terminal of the secondary side coil 432s is connected to an application terminal of the rectified voltage V1. A second terminal of the capacitor C2 is connected to the external terminal T5. The diode D2 and the capacitor C2 are understood as a rectifying circuit REC2, which rectifies and smooths the sum voltage (V1+Vs2) of the rectified voltage V1 and the induction voltage Vs2 generated in the secondary side coil 432s, so as to generate the rectified voltage V2. The capacitor C2 may have a capacitance of 1 pF, for example. In other words, C1>>C2 may hold. The capacitor C2 may be eliminated.

The gate of the transistor P1 is connected to the application terminal of the rectified voltage V1. The source of the transistor P1 is connected to the second terminal of the resistor R0. The drain of the transistor P1 is connected to the application terminal of the switch drive signal Vg. The transistor P1 conducts or cuts off between the application terminal of the rectified voltage V2 and the application terminal of the switch drive signal Vg, in accordance with the gate-source voltage, i.e., the difference voltage (V2−V1) between the rectified voltage V1 and the rectified voltage V2.

In addition, in the isolation switch 400 of this embodiment, along with the configuration change of the switch driving circuit 421, operation of each of the pulse generation circuits 411 and 412 is also changed.

For instance, when the input pulse signal DIN is at high level, the pulse generation circuit 412 generates the transmission pulse signal Vp2, so as to perform pulse drive of the primary side coil 432p. In other words, when raising the switch drive signal Vg to high level, the pulse generation circuit 412 performs pulse drive of the primary side coil 432p. On the other hand, when the input pulse signal DIN is at low level, the pulse generation circuit 412 stops generation of the transmission pulse signal Vp2, so as to stop pulse drive of the primary side coil 432p. In other words, when decreasing the switch drive signal Vg to low level, the pulse generation circuit 412 stops pulse drive of the primary side coil 432p. This operation is the same as in the first embodiment described above.

In contrast, the pulse generation circuit 411 generates the transmission pulse signal Vp1 and performs pulse drive of the primary side coil 432p, not only when the input pulse signal DIN is at high level, but also when it is at low level. In other words, the pulse generation circuit 412 performs pulse drive of the primary side coil 411p, not only when increasing the switch drive signal Vg to high level but also when decreasing the same to low level.

Next, a basic operation of the isolation switch 400 in this embodiment is described below. During the high level period of the input pulse signal DIN, the transmission pulse signal Vp1 applied to the primary side coil 431p is pulse-driven. Therefore, the induction voltage Vs1 is generated across both terminals of the secondary side coil 431s. When the induction voltage Vs1 is rectified and smoothed in the rectifying circuit REC1, the rectified voltage V1 is generated. The rectified voltage V1 may be 4 V, for example.

In addition, during the high level period of the input pulse signal DIN, the transmission pulse signal Vp2 applied to the primary side coil 432p is pulse-driven. Therefore, the induction voltage Vs2 is generated across both terminals of the secondary side coil 432s. In this case, the anode of the diode D2 is applied with the sum voltage (V1+Vs2) of the rectified voltage V1 and the induction voltage Vs2. When the sum voltage (V1+Vs2) is rectified and smoothed in the rectifying circuit REC2, the rectified voltage V2 is generated. The rectified voltage V2 may be 8 V, for example.

When the difference voltage (V2−V1) between the rectified voltage V1 and the rectified voltage V2 becomes higher than the ON threshold value voltage Vth(P1) of the transistor P1, the transistor P1 becomes ON state. Therefore, the path between the application terminal of the rectified voltage V2 and the application terminal of the switch drive signal Vg becomes conductive. In this case, the switch drive signal Vg is raised to a signal level higher than the ON threshold value voltage Vth(M1) of the transistor M1, i.e., to high level (≈V2). As a result, the transistor M1 becomes ON state, and hence the load ZL1 can be supplied with the drive current.

Note that in this diagram, each of the arrows added to the primary side coils 431p and 432p, as well as the secondary side coils 431s and 432s, respectively, indicates a direction of current that flows when the switch drive signal Vg is raised to high level.

In contrast, during the low level period of the input pulse signal DIN, the pulse drive of the transmission pulse signal Vp1 is continued, while pulse drive of the transmission pulse signal Vp2 is stopped. In this case, the induction voltage Vs1 is generated in the secondary side coil 431s, and hence the charge accumulated in the capacitor C1, i.e., the rectified voltage V1 is maintained.

However, the induction voltage Vs2 is not generated in the secondary side coil 432s. For this reason, charge supply to the capacitor C2, as well as charge supply to the capacitor Cg is stopped. Therefore, a charge discharge amount via the discharge circuit 421X exceeds a charge supply amount via the transistor P1. As a result, the switch drive signal Vg is decreased.

Note that along with a decrease in the switch drive signal Vg, the rectified voltage V2 is also decreased. Then, the difference voltage (V2−V1) between the rectified voltage V1 and the rectified voltage V2 becomes below the ON threshold value voltage Vth(P1) of the transistor P1, and the transistor P1 becomes OFF state. As a result, the decrease in the rectified voltage V2 is stopped. In other words, the rectified voltage V2 is maintained at a value near the rectified voltage V1. After that, too, the switch drive signal Vg is decreased to a signal level lower than the ON threshold value voltage Vth(M1) of the transistor M1, by the action of the discharge circuit 421X. As a result, the transistor M1 becomes OFF state, and hence the load ZL1 is not supplied with the drive current.

Here, as described above, charges stored in the capacitors C1 and C2, respectively, are maintained also during the low level period of the input pulse signal DIN. Therefore, when the input pulse signal DIN is raised to high level next time, the rectified voltage V2 starts to increase from the state where charges are stored in the capacitors C1 and C2, respectively. As a result, turn-off timing of the transistor P1 is accelerated, and hence the switch drive signal Vg is raised to high level more quickly.

As described above, compared with the first embodiment described above (FIG. 11), the isolation switch 400 of this embodiment can shorten rising time of the switch drive signal Vg at the second time and thereafter.

### Isolation Switch (Third Embodiment)

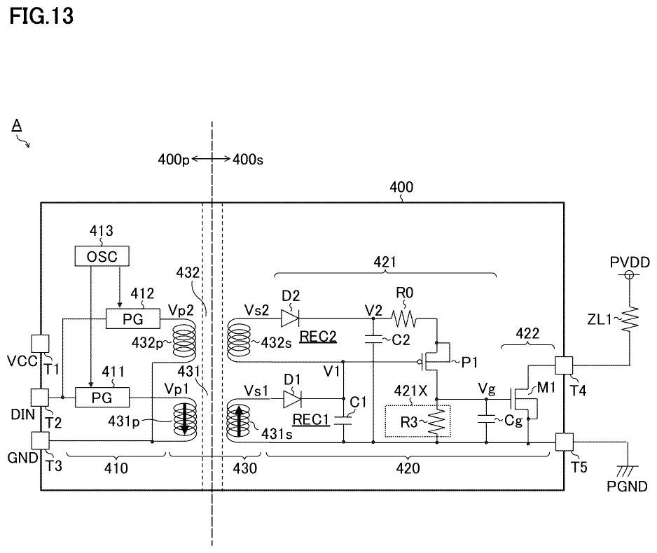

FIG. 13 is a diagram illustrating a third embodiment of the isolation switch 400. The isolation switch 400 of this embodiment uses the second embodiment described above (FIG. 12) as a base and includes a resistor R3 as the discharge circuit 421X that discharges the switch drive signal Vg.

The resistor R3 can be understood as a discharge resistor that is connected between the application terminal of the switch drive signal Vg and the external terminal T5. In the isolation switch 400 of this embodiment, the discharge circuit 421X can be formed very simply.

### Isolation Switch (Fourth Embodiment)

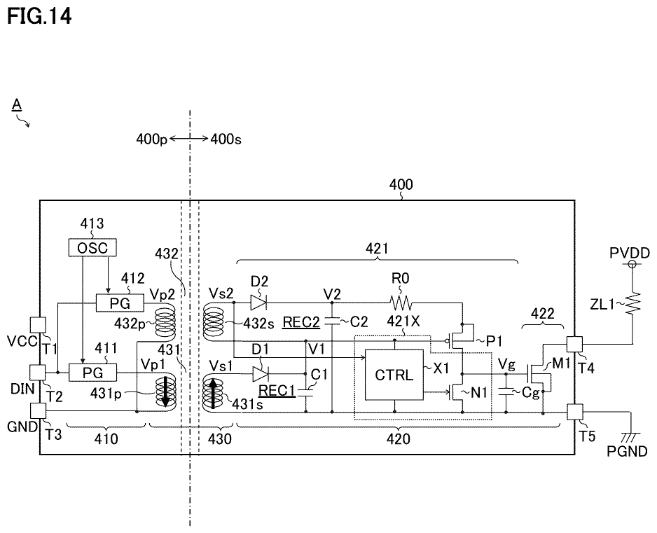

FIG. 14 is a diagram illustrating a fourth embodiment of the isolation switch 400. The isolation switch 400 of this embodiment uses the second embodiment described above (FIG. 12) as a base and includes a transistor N1 and a controller X1 as component elements of the discharge circuit 421X. The transistor N1 may be an N-channel type, for example.

The drain of the transistor N1 is connected to the application terminal of the switch drive signal Vg. The source of the transistor N1 is connected to the external terminal T5. The transistor N1 functions as a low-impedance discharge switch connected between the application terminal of the switch drive signal Vg and the external terminal T5.

The controller X1 drives the gate of the transistor N1 in accordance with the induction voltage Vs2 generated in the secondary side coil 432s, for example. For instance, the controller X1 sets the transistor N1 to ON state when the induction voltage Vs2 is not generated. On the other hand, the controller X1 sets the transistor N1 to OFF state when the induction voltage Vs2 is generated.

Note that the controller X1 may operate by the rectified voltage V1 as power supply. Alternatively, the controller X1 may operate by the switch drive signal Vg as power supply.

Compared with the third embodiment described above (FIG. 13), the isolation switch 400 of this embodiment can discharge the switch drive signal Vg more quickly. Therefore, fast switching of the transistor M1 can be performed.

### Controller

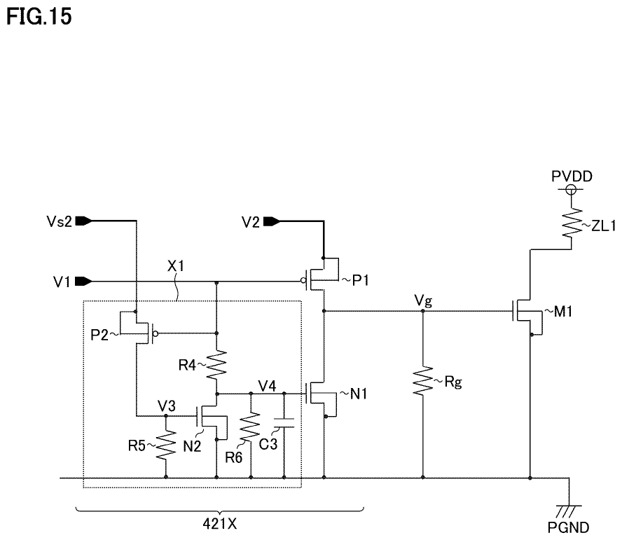

FIG. 15 is a diagram illustrating one configuration example of the controller X1. The controller X1 of this configuration example operates by the rectified voltage V1 as power supply. With reference to this diagram, the controller X1 includes a capacitor C3, a transistor N2, a transistor P2, and resistors R4 to R6. Note that the transistor N2 may be an N-channel type, for example. In addition, the transistor P2 may be a P-channel type, for example. A resistor Rg may be connected between the gate and the source of the transistor M1.

The source of the transistor P2 is connected to the application terminal of the induction voltage Vs2. The gate of the transistor P2 and a first terminal of the resistor R4 are connected to the application terminal of the rectified voltage V1. The drain of the transistor P2, the gate of the transistor N2, and a first terminal of the resistor R5 are connected to an application terminal of a voltage signal V3. A second terminal of the resistor R4, the drain of the transistor N2, and first terminals of the resistor R6 and the capacitor C3 are connected to an application terminal of a voltage signal V4. The source of the transistor N2, second terminals of the resistors R5 and R6, and a second terminal of the capacitor C3 are connected to the application terminal of the ground voltage PGND. The application terminal of the voltage signal V4 is connected to the gate of the transistor N1 as an output terminal of the controller X1.

When the induction voltage Vs2 is not generated, the transistor P2 is in OFF state, and hence the voltage signal V3 is at low level (≈PGND). In this case, the transistor N2 is in OFF state, and hence the voltage signal V4 is at high level (≈V1). Therefore, the transistor N1 is in ON state. On the other hand, when the induction voltage Vs2 is generated, the transistor P2 is in ON state, and hence the voltage signal V3 is at high level (≈V1+Vs2). In this case, the transistor N2 is in ON state, and hence the voltage signal V4 is at low level (≈PGND). Therefore, the transistor N1 is in OFF state.

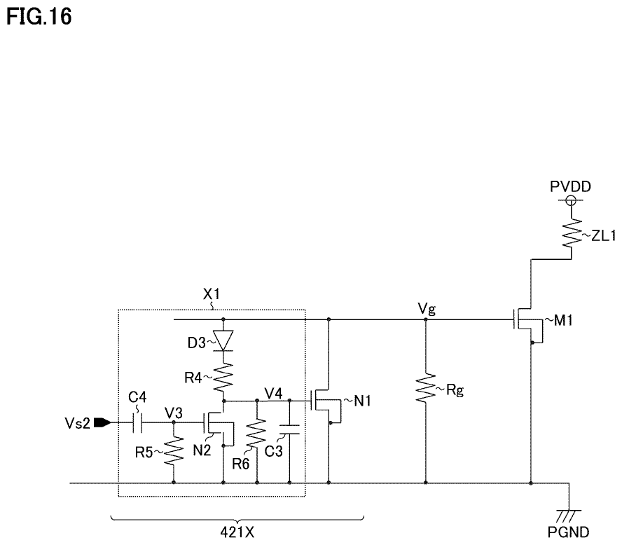

FIG. 16 is a diagram illustrating one variation of the controller X1. The controller X1 of this variation uses the configuration example described above (FIG. 15) as a base, and operates by the switch drive signal Vg as power supply. With reference to this diagram, the controller X1 includes a capacitor C4 and a diode D3 instead of the transistor P2.

The anode of the diode D3 is connected to the application terminal of the switch drive signal Vg. The cathode of the diode D3 is connected to the first terminal of the resistor R4. A first terminal of the capacitor C4 is connected to the application terminal of the induction voltage Vs2. A second terminal of the capacitor C4 is connected to the application terminal of the voltage signal V3.

When the induction voltage Vs2 is not generated, the voltage signal V3 is at low level (≈PGND), and hence the transistor N2 is in OFF state. Therefore, the voltage signal V4 is at high level (≈V1), and hence the transistor N1 is in ON state. On the other hand, when the induction voltage Vs2 is generated, the voltage signal V3 is at high level (≈V1+Vs2), and hence the transistor N2 is in ON state. Therefore, the voltage signal V4 is at low level (≈PGND), and hence the transistor N1 is in OFF state.

### Isolation Switch (Fifth Embodiment)

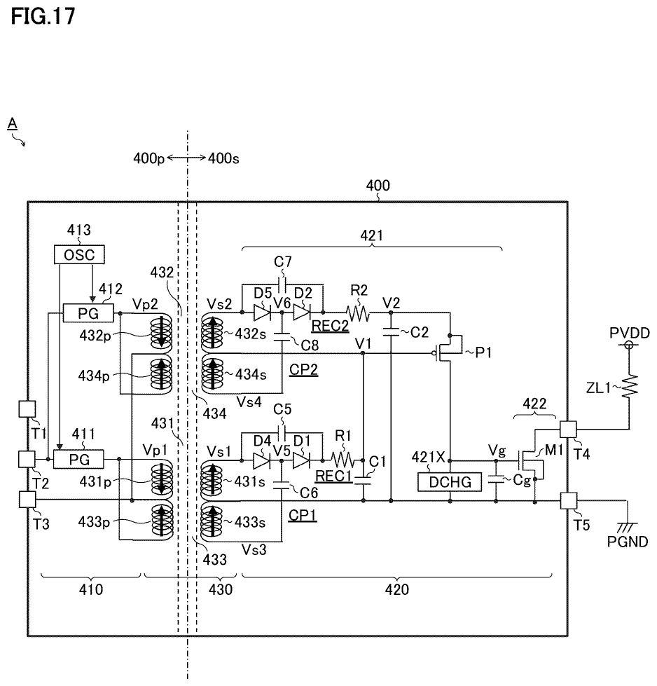

FIG. 17 is a diagram illustrating a fifth embodiment of the isolation switch 400. The isolation switch 400 of this embodiment uses the second embodiment described above (FIG. 12) as a base, and further includes transformers 433 and 434, capacitors C5 to C8, diodes D4 and D5, and resistors R1 and R2. The transformer 433 includes a primary side coil 433p and a secondary side coil 433s. In addition, the transformer 434 includes a primary side coil 434p and a secondary side coil 434s. On the other hand, the resistor R0 described above is eliminated.

A first terminal of the primary side coil 433p is connected to the application terminal of the transmission pulse signal Vp1. A first terminal of the primary side coil 434p is connected to the application terminal of the transmission pulse signal Vp2. Second terminals of the primary side coils 433p and 434p are each connected to the external terminal T3. In other words, similarly to the primary side coils 431p and 432p described above, the primary side coils 433p and 434p are connected in parallel between the application terminal of the power supply voltage VCC and the application terminal of the ground voltage GND. Then, conduction/non-conduction of each of the primary side coils 433p and 434p is switched in accordance with the input pulse signal DIN.

In other words, the pulse generation circuit 411 performs pulse drives of the primary side coils 431p and 433p simultaneously. In addition, the pulse generation circuit 412 performs pulse drives of the primary side coils 432p and 434p simultaneously.

The first terminal of the secondary side coil 431s, the anode of the diode D4, and a first terminal of the capacitor C5 are connected to the application terminal of the induction voltage Vs1. The cathode of the diode D4, the anode of the diode D1, and a first terminal of the capacitor C6 are connected to an application terminal of a boost voltage V5. The cathode of the diode D1 and a second terminal of the capacitor C5 are connected to a first terminal of the resistor R1. A second terminal of the resistor R1 and a first terminal of the capacitor C1 are connected to the application terminal of the rectified voltage V1. The second terminal of the secondary side coil 431s, a first terminal of the secondary side coil 433s, and the second terminal of the capacitor C1 are connected to the external terminal T5. A second terminal of the secondary side coil 433s is connected to a second terminal of the capacitor C6.

The diode D4 and the capacitor C6 can be understood as a boost circuit CP1 that generates the boost voltage V5 from the induction voltage Vs1 generated in the secondary side coil 431s and an induction voltage Vs3 generated in the secondary side coil 433s. The boost circuit CP1 increases an amplitude of the boost voltage V5 to be higher than that of each of the induction voltages Vs1 and Vs3, by a charge pump operation using the induction voltages Vs1 and Vs3 that are pulse-driven in differential form.

The diode D1, the resistor R1, and the capacitor C1 can be understood as the rectifying circuit REC1 that rectifies the boost voltage V5 so as to generate the rectified voltage V1.

The first terminal of the secondary side coil 432s, the anode of the diode D5, and a first terminal of the capacitor C7 are connected to the application terminal of the induction voltage Vs2. The cathode of the diode D5, the anode of the diode D2, and a first terminal of the capacitor C8 are connected to an application terminal of a boost voltage V6. The cathode of the diode D2 and a second terminal of the capacitor C7 are connected to a first terminal of the resistor R2. A second terminal of the resistor R2 and a first terminal of the capacitor C2 are connected to the application terminal of the rectified voltage V2. The second terminal of the secondary side coil 432s and a first terminal of the secondary side coil 434s are connected to the application terminal of the rectified voltage V1. The second terminal of the capacitor C2 is connected to the external terminal T5. A second terminal of the secondary side coil 434s is connected to a second terminal of the capacitor C8.

The diode D5 and the capacitor C8 can be understood as a boost circuit CP2 that generates the boost voltage V6 from the induction voltage Vs2 generated in the secondary side coil 432s and an induction voltage Vs4 generated in the secondary side coil 434s. The boost circuit CP2 increases an amplitude of the boost voltage V6 to be higher than that of each of the induction voltages Vs2 and Vs4, by a charge pump operation using the induction voltages Vs2 and Vs4 that are pulse-driven in differential form.

The diode D2, the resistor R2, and the capacitor C2 can be understood as the rectifying circuit REC2 that rectifies the sum voltage of the rectified voltage V1 and the boost voltage V6, so as to generate the rectified voltage V2.

The gate of the transistor P1 is connected to the application terminal of the rectified voltage V1. The source of the transistor P1 is connected to the application terminal of the rectified voltage V2. The drain of the transistor P1 is connected to the application terminal of the switch drive signal Vg. The transistor P1 conducts or cuts off between the application terminal of the rectified voltage V2 and the application terminal of the switch drive signal Vg, in accordance with the gate-source voltage, i.e., the difference voltage (V2−V1) between the rectified voltage V1 and the rectified voltage V2.

Compared with the second embodiment (FIG. 12) described above, the isolation switch 400 of this embodiment can further increase high level of the switch drive signal Vg, by the action of the boost circuits CP1 and CP2.

### Isolation Switch (Sixth Embodiment)

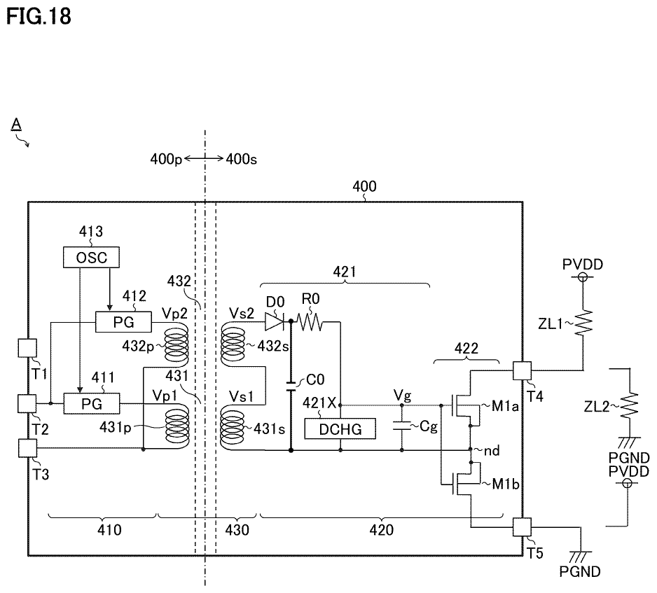

FIG. 18 is a diagram illustrating a sixth embodiment of the isolation switch 400. The isolation switch 400 of this embodiment uses the first embodiment described above (FIG. 11) as a base, in which the configuration of the switch circuit 422 is modified. With reference to this diagram, the switch circuit 422 includes transistors M1a and M1b instead of the transistor M1 described above. The transistors M1a and M1b may be each an N-channel type, for example.

The source and the backgate of each of the transistors M1a and M1b are connected to a common node n1. The common node n1 is also connected to the second terminal of the secondary side coil 431s and a second terminal of the capacitor Cg. The gate of each of the transistors M1a and M1b is connected to the application terminal of the switch drive signal Vg.

In a first connection mode, the drain of the transistor M1a is connected to the application terminal of the power supply voltage PVDD via the load ZL1, and the drain of the transistor M1b can be connected to the application terminal of the ground voltage PGND. In this case, the switch circuit 422 functions as a low side switch.

In a second connection mode, the drain of the transistor M1a is connected to the application terminal of the ground voltage PGND via a load ZL2, and the drain of the transistor M1b can be connected to the application terminal of the power supply voltage PVDD. In this case, the switch circuit 422 functions as an upper side switch.

In this way, the isolation switch 400 of this embodiment can be flexibly used even if one of the external terminals T4 and T5 is a high potential node.

### Isolation Switch (Seventh Embodiment)

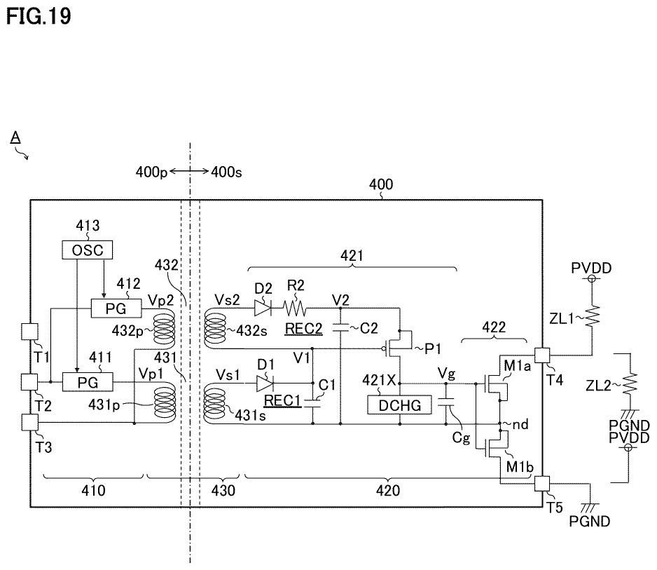

FIG. 19 is a diagram illustrating a seventh embodiment of the isolation switch 400. The isolation switch 400 of this embodiment uses the second embodiment described above (FIG. 12) as a base, and the switch circuit 422 includes the transistors M1a and M1b, similarly to the sixth embodiment described above (FIG. 18).

The isolation switch 400 of this embodiment can obtain the same action and effect as the sixth embodiment described above (FIG. 18), and can realize faster switching.

### Isolation Switch (Eighth Embodiment)

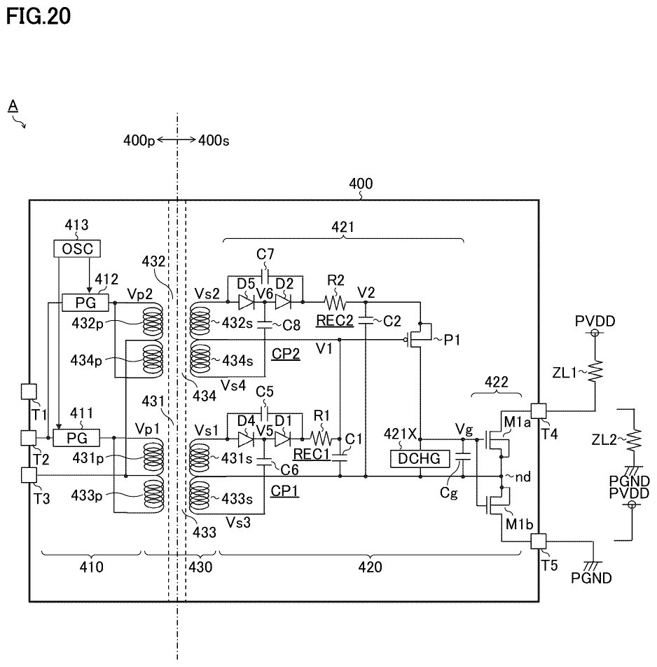

FIG. 20 is a diagram illustrating an eighth embodiment of the isolation switch 400. The isolation switch 400 of this embodiment uses the fifth embodiment described above (FIG. 17) as a base, and the switch circuit 422 includes the transistors M1a and M1b similarly to the sixth embodiment described above (FIG. 18).

The isolation switch 400 of this embodiment can obtain the same action and effect as the sixth embodiment described above (FIG. 18), and can generate the switch drive signal Vg of higher level.

### Isolation Switch (Ninth Embodiment)

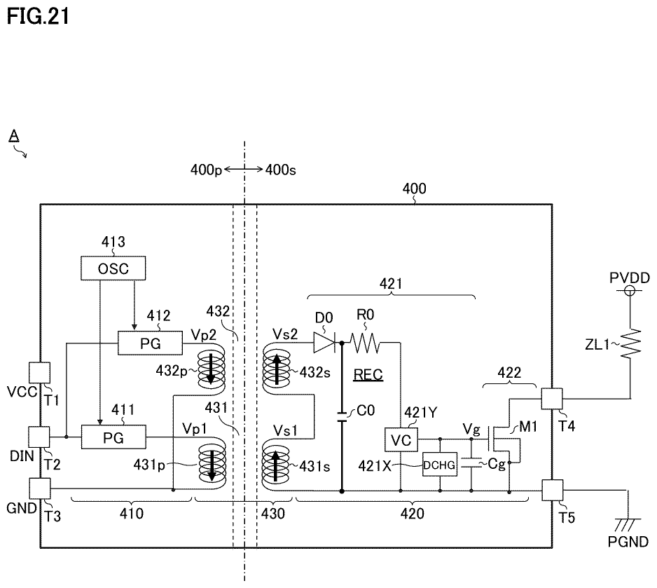

FIG. 21 is a diagram illustrating a ninth embodiment of the isolation switch 400. The isolation switch 400 of this embodiment uses the first embodiment described above (FIG. 11) as a base and further includes a voltage control circuit 421Y as a component element of the switch driving circuit 421.

If a GaN device or the like is used as the transistor M1, the switch drive signal Vg is required to have a certain degree of accuracy. For instance, the switch drive signal Vg may be required to have an output accuracy of 5 V±10%. However, the rectifying circuit REC constituted of the diode D0 and the capacitor C0 may not always be able to have the above output accuracy.

Therefore, the isolation switch 400 of this embodiment includes the voltage control circuit 421Y as an component element of the switch driving circuit 421. The voltage control circuit 421Y is preferably disposed between the rectifying circuit REC and the application terminal of the switch drive signal Vg. The voltage control circuit 421Y stabilizes the switch drive signal Vg and outputs the same to the gate of the transistor M1. With this configuration, the transistor M1 can be appropriately driven.

### Isolation Switch (Tenth Embodiment)

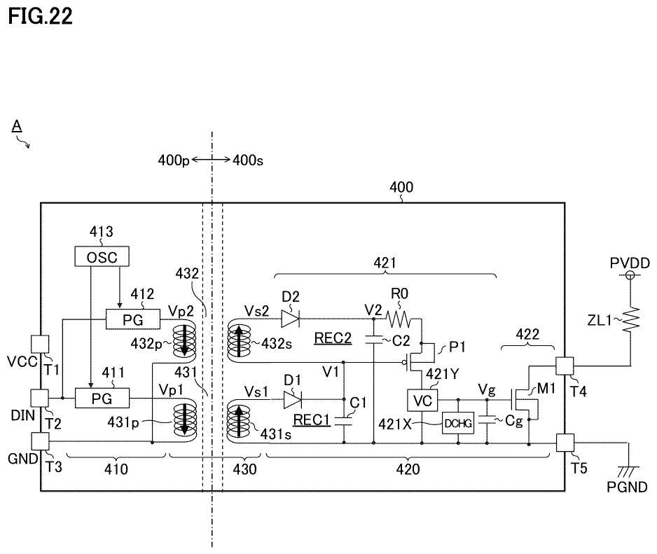

FIG. 22 is a diagram illustrating a tenth embodiment of the isolation switch 400. The isolation switch 400 of this embodiment uses the second embodiment described above (FIG. 12) as a base and further includes the voltage control circuit 421Y as a component element of the switch driving circuit 421. As illustrated in this diagram, the voltage control circuit 421Y can be introduced to the switch driving circuit 421 having various topology, without regard to the configuration of the pre-stage circuit (the rectifying circuits REC1 and REC2 in this diagram).

### Voltage Control Circuit

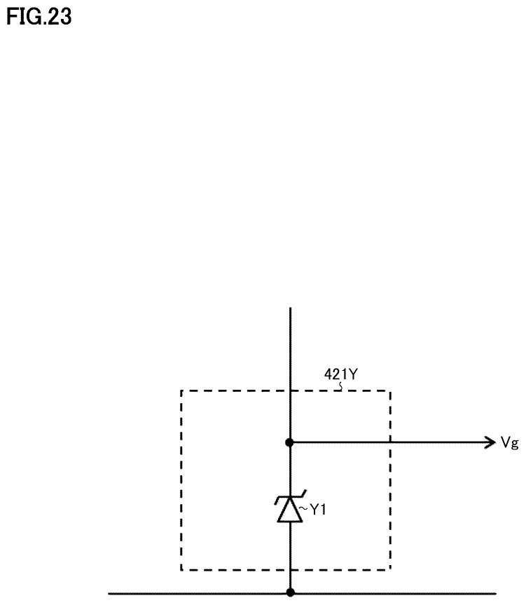

FIG. 23 is a diagram illustrating one configuration example of the voltage control circuit 421Y. The voltage control circuit 421Y of this configuration example includes a zener diode Y1. The cathode of the zener diode Y1 is connected to the application terminal of the switch drive signal Vg. The anode of the zener diode Y1 is connected to the external terminal T5. The external terminal T5 can be understood as one example of a reference potential terminal. With this configuration, the voltage control circuit 421Y can be easily mounted.

### Combination of Embodiments

The various embodiments described above may be arbitrarily combined within a range in which no contradiction occurs. For instance, the third embodiment (FIG. 13) and the fourth embodiment (FIG. 14) may be applied simultaneously. In other words, the discharge circuit 421X may include a first discharge path via the resistor R3 and a second discharge path via the transistor N1.

In addition, the voltage control circuit 421Y described above can be introduced to any one of the third embodiment (FIG. 13), the fourth embodiment (FIG. 14), the fifth embodiment (FIG. 17), the sixth embodiment (FIG. 18), the seventh embodiment (FIG. 19), and the eighth embodiment (FIG. 20). Note that when introducing the voltage control circuit 421Y, if the output circuit 422 includes the transistors M1a and M1b, the anode of the zener diode Y1 is preferably connected to a common node nd instead of the external terminal T5. The common node nd can be understood as one example of a reference potential terminal.

### Additional Notes

According to the present disclosure, high level of the switch drive signal is increased. Additional Notes related to the above disclosure are described below.

### Additional Note 1

An isolation switch (400) includes:
a switch circuit (422) connected between a first node (T4) and a second node (T5), being configured to be turned on and off by a switch drive signal (Vg);
a first transformer (431) and a second transformer (432) configured to have a first primary side coil (431p) and a second primary side coil (432p) connected in parallel between a power supply terminal (VCC) and a ground terminal (GND), and a first secondary side coil (431s) and a second secondary side coil (432s) connected in series;
a first pulse generation circuit (411) and a second pulse generation circuit (412) configured to pulse-drive the first primary side coil (431p) and the second primary side coil (432p), respectively, in accordance with an input pulse (DIN); and
a switch driving circuit (421) configured to receive induction voltages (Vs1, Vs2) generated in the first secondary side coil (431s) and the second secondary side coil (432s), respectively, so as to generate the switch drive signal (Vg).

### Additional Note 2

In the isolation switch (400) described in Additional Note 1, the switch circuit (422) includes at least one output transistor (M1, M1a, M1b) having the gate connected to an application terminal of the switch drive signal (Vg).

### Additional Note 3

In the isolation switch (400) described in Additional Note 2, the output transistor (M1, M1a, M1b) is a GaN device or an SiC device.

### Additional Note 4

In the isolation switch (400) described in Additional Note 2 or 3, the switch driving circuit (421) is configured to rectify the sum voltage of a first induction voltage (Vs1) generated in the first secondary side coil (431s) and a second induction voltage (Vs2) generated in the second secondary side coil (432s), so as to generate the switch drive signal (Vg).

### Additional Note 5

In the isolation switch (400) described in Additional Note 4, the first pulse generation circuit (411) and the second pulse generation circuit (412) are configured to perform pulse drives of the first primary side coil (431p) and the second primary side coil (432p), respectively, when the input pulse (DIN) is at a first logic level (e.g., high level), and to stop the pulse drives of the first primary side coil (431p) and the second primary side coil (432p), respectively, when the input pulse (DIN) is at a second logic level (e.g., low level).

### Additional Note 6

In the isolation switch (400) described in Additional Note 2 or 3, the switch driving circuit (421) includes a first rectifying circuit (REC1) configured to rectify a first induction voltage (Vs1) generated in the first secondary side coil (431s), so as to generate a first rectified voltage (V1), a second rectifying circuit (REC2) configured to rectify the sum voltage of the first rectified voltage (V1) and a second induction voltage (Vs2) generated in the second secondary side coil (432s), so as to generate a second rectified voltage (V2), and a transistor (P1) configured to conduct or cut off between an application terminal of the second rectified voltage (V2) and an application terminal of the switch drive signal (Vg), in accordance with a difference voltage between the first rectified voltage (V1) and the second rectified voltage (V2).

### Additional Note 7

In the isolation switch (400) described in Additional Note 6, the first rectifying circuit (REC1) includes a first diode (D1) configured to be connected between an application terminal of the first induction voltage (Vs1) and an application terminal of the first rectified voltage (V1), and a first capacitor (C1) configured to be connected between an application terminal of the first rectified voltage (V1) and the second node (T5). The second rectifying circuit (REC2) includes a second diode (D2) configured to be connected between an application terminal of the second induction voltage (Vs2) and an application terminal of the second rectified voltage (V2).

### Additional Note 8

In the isolation switch (400) described in Additional Note 7, the second rectifying circuit (REC2) further includes a second capacitor (C2) configured to be connected between an application terminal of the second rectified voltage (V2) and the second node (T5).

### Additional Note 9

In the isolation switch (400) described in any one of Additional Notes 6 to 8, the first pulse generation circuit (411) is configured to perform pulse drive of the first primary side coil (431p), not only when the input pulse (DIN) is at a first logic level (e.g., high level) but also when the same is at a second logic level (e.g., low level), and the second pulse generation circuit (412) is configured to perform pulse drive of the second primary side coil (432p) when the input pulse (DIN) is at the first logic level (e.g., high level), and to stop the pulse drive of the second primary side coil (432p) when the input pulse (DIN) is at the second logic level (e.g., low level).

### Additional Note 10

In the isolation switch (400) described in any one of Additional Notes 2 to 9, the switch driving circuit (421) includes a discharge circuit (421X) configured to discharge the switch drive signal (Vg).

### Additional Note 11

In the isolation switch (400) described in Additional Note 10, the discharge circuit (421X) includes a discharge resistor (R3) configured to be connected between an application terminal of the switch drive signal (Vg) and the second node (T5).

### Additional Note 12

In the isolation switch (400) described in any one of Additional Notes 6 to 9, the switch driving circuit (421) includes a discharge switch (N1) configured to be connected between an application terminal of the switch drive signal (Vg) and the second node (T5), and a controller (X1) configured to drive the discharge switch (N1) in accordance with the second induction voltage (Vs2).

### Additional Note 13

In the isolation switch (400) described in Additional Note 12, the controller (X1) operates by the first rectified voltage (V1) or the switch drive signal (Vg) as power supply.

### Additional Note 14

The isolation switch (400) described in Additional Note 2 or 3 further includes:
a third transformer (433) having a third primary side coil (433p) and a third secondary side coil (433s); and
a fourth transformer (434) having a fourth primary side coil (434p) and a fourth secondary side coil (434s), in which
the first pulse generation circuit (411) simultaneously performs pulse drives of the first primary side coil (431p) and the third primary side coil (433p),
the second pulse generation circuit (412) simultaneously performs pulse drives of the second primary side coil (432p) and the fourth primary side coil (434p), and
the switch driving circuit (421) includes a first boost circuit (CP1) configured to generate a first boost voltage (V5), from a first induction voltage (Vs1) generated in the first secondary side coil (431s) and a third induction voltage (Vs3) generated in the third secondary side coil (433s); a first rectifying circuit (REC1) configured to rectify the first boost voltage (V5) so as to generate a first rectified voltage (V1); a second boost circuit (CP2) configured to generate a second boost voltage (V6), from a second induction voltage (Vs2) generated in the second secondary side coil (432s) and a fourth induction voltage (Vs4) generated in the fourth secondary side coil (434s); a second rectifying circuit (REC2) configured to rectify the sum voltage of the first rectified voltage (V1) and the second boost voltage (V6) so as to generate a second rectified voltage (V2); and a transistor (P1) configured to conduct or cut off between an application terminal of the second rectified voltage (V2) and an application terminal of the switch drive signal (Vg), in accordance with a difference voltage between the first rectified voltage (V1) and the second rectified voltage (V2).

### Additional Note 15

In the isolation switch (400) described in any one of Additional Notes 2 to 14, the switch circuit (422) includes a first output transistor (M1a) and a second output transistor (M1b) as the output transistors (M1), each of which has the gate connected to an application terminal of the switch drive signal (Vg), and the source connected to a common node.

### Additional Note 16

In the isolation switch (400) described in any one of Additional Notes 1 to 15, the switch driving circuit (421) includes a voltage control circuit (421Y) configured to stabilize the switch drive signal (Vg).

### Additional Note 17

In the isolation switch (400) described in Additional Note 16, the voltage control circuit (421Y) includes a zener diode (Y1) configured to be connected between an application terminal of the switch drive signal (Vg) and a reference potential terminal (T5, nd).

### Others

Note that other than the embodiments described above, various technical features disclosed in this specification can be variously modified within the scope of the technical invention without deviating from the spirit thereof. In other words, the embodiments described above are examples in every aspect and should not be interpreted as limitations. In addition, the technical scope of the present disclosure is defined by the claims and should be understood to include all modifications within meaning and scope equivalent to the claims.

What is claimed is:

1. An isolation switch comprising:
a switch circuit connected between a first node and a second node, being configured to be turned on and off by a switch drive signal;
a first transformer and a second transformer configured to have a first primary side coil and a second primary side coil connected in parallel between a power supply terminal and a ground terminal, and a first secondary side coil and a second secondary side coil connected in series;
a first pulse generation circuit and a second pulse generation circuit configured to pulse-drive the first primary side coil and the second primary side coil, respectively, in accordance with an input pulse; and
a switch driving circuit configured to receive induction voltages generated in the first secondary side coil and the second secondary side coil, respectively, so as to generate the switch drive signal.

2. The isolation switch according to claim 1, wherein the switch circuit includes at least one output transistor having the gate connected to an application terminal of the switch drive signal.

3. The isolation switch according to claim 2, wherein the output transistor is a GaN device or a SiC device.

4. The isolation switch according to claim 2, wherein the switch driving circuit is configured to rectify the sum voltage of a first induction voltage generated in the first secondary side coil and a second induction voltage generated in the second secondary side coil, so as to generate the switch drive signal.

5. The isolation switch according to claim 4, wherein the first pulse generation circuit and the second pulse generation circuit are configured to perform pulse drives of the first primary side coil and the second primary side coil, respectively, when the input pulse is at a first logic level, and to stop the pulse drives of the first primary side coil and the second primary side coil, respectively, when the input pulse is at a second logic level.

6. The isolation switch according to claim 2, wherein the switch driving circuit includes:
a first rectifying circuit configured to rectify a first induction voltage generated in the first secondary side coil, so as to generate a first rectified voltage;
a second rectifying circuit configured to rectify the sum voltage of the first rectified voltage and a second induction voltage generated in the second secondary side coil, so as to generate a second rectified voltage; and
a transistor configured to conduct or cut off between an application terminal of the second rectified voltage and an application terminal of the switch drive signal, in accordance with a difference voltage between the first rectified voltage and the second rectified voltage.

7. The isolation switch according to claim 6, wherein
the first rectifying circuit includes a first diode configured to be connected between an application terminal of the first induction voltage and an application terminal of the first rectified voltage, and a first capacitor configured to be connected between an application terminal of the first rectified voltage and the second node, and
the second rectifying circuit includes a second diode configured to be connected between an application terminal of the second induction voltage and an application terminal of the second rectified voltage.

8. The isolation switch according to claim 7, wherein the second rectifying circuit further includes a second capacitor configured to be connected between an application terminal of the second rectified voltage and the second node.

9. The isolation switch according to claim 6, wherein
the first pulse generation circuit is configured to perform pulse drive of the first primary side coil, not only when the input pulse is at a first logic level but also when the same is at a second logic level,
the second pulse generation circuit is configured to perform pulse drive of the second primary side coil when the input pulse is at the first logic level, and to stop the pulse drive of the second primary side coil when the input pulse is at the second logic level.

10. The isolation switch according to claim 2, wherein the switch driving circuit includes a discharge circuit configured to discharge the switch drive signal.

11. The isolation switch according to claim 10, wherein the discharge circuit includes a discharge resistor configured to be connected between an application terminal of the switch drive signal and the second node.

12. The isolation switch according to claim 6, wherein the switch driving circuit includes:
a discharge switch configured to be connected between an application terminal of the switch drive signal and the second node, and
a controller configured to drive the discharge switch in accordance with the second induction voltage.

13. The isolation switch according to claim 12, wherein the controller operates by the first rectified voltage or the switch drive signal as power supply.

14. The isolation switch according to claim 2, further comprising:
a third transformer including a third primary side coil and a third secondary side coil; and
a fourth transformer including a fourth primary side coil and a fourth secondary side coil, wherein
the first pulse generation circuit simultaneously performs pulse drives of the first primary side coil and the third primary side coil,
the second pulse generation circuit simultaneously performs pulse drives of the second primary side coil and the fourth primary side coil, and
the switch driving circuit includes:
a first boost circuit configured to generate a first boost voltage from a first induction voltage generated in the first secondary side coil and a third induction voltage generated in the third secondary side coil;
a first rectifying circuit configured to rectify the first boost voltage so as to generate a first rectified voltage;
a second boost circuit configured to generate a second boost voltage from a second induction voltage generated in the second secondary side coil and a fourth induction voltage generated in the fourth secondary side coil;
a second rectifying circuit configured to rectify the sum voltage of the first rectified voltage and the second boost voltage so as to generate a second rectified voltage; and
a transistor configured to conduct or cut off between an application terminal of the second rectified voltage and an application terminal of the switch drive signal, in accordance with a difference voltage between the first rectified voltage and the second rectified voltage.

15. The isolation switch according to claim 2, wherein the switch circuit includes a first output transistor and a second output transistor as the output transistors, each of which has the gate connected to an application terminal of the switch drive signal, and the source connected to a common node.

16. The isolation switch according to claim 1, wherein the switch driving circuit includes a voltage control circuit configured to stabilize the switch drive signal.

17. The isolation switch according to claim 16, wherein the voltage control circuit includes a zener diode configured to be connected between an application terminal of the switch drive signal and a reference potential terminal.
